(19) United States
(12) Patent Application Publication
(10) Pub. No.: US 2025/0264796 A1
(43) Pub. Date: Aug. 21, 2025

(54) SEMICONDUCTOR PHOTORESIST COMPOSITIONS AND METHODS OF FORMING PATTERNS USING THE COMPOSITION

(71) Applicant: SAMSUNG SDI CO., LTD., Yongin-si (KR)

(72) Inventor: Young Keun KIM, Suwon-si (KR)

(21) Appl. No.: 18/972,520

(22) Filed: Dec. 6, 2024

(30) Foreign Application Priority Data
Feb. 15, 2024 (KR) 10-2024-0022094

(51) Int. Cl. G03F 7/004; C07F 7/22; G03F 7/00; H01L 21/027; H01L 21/311

(52) U.S. Cl. CPC G03F 7/0042; C07F 7/2224; G03F 7/70033; H01L 21/0271; H01L 21/31144

(57) ABSTRACT

A semiconductor photoresist composition and a method of forming patterns using the semiconductor photoresist composition are provided. The semiconductor photoresist composition includes a first organometallic compound represented by (R¹)ₐ-M¹-X¹_{b}, a second organometallic compound represented by (R²)_{c}-M²-X²_{d}, and a solvent.

### CROSS-REFERENCE TO RELATED APPLICATION

The present application claims priority to and the benefit of Korean Patent Application No. 10-2024-0022094, filed on Feb. 15, 2024, in the Korean Intellectual Property Office, the entire content of which is incorporated herein by reference.

### BACKGROUND

### 1. Field

One or more embodiments of the present disclosure relate to semiconductor photoresist compositions and methods of forming patterns using the semiconductor photoresist composition.

### 2. Description of the Related Art

EUV (extreme ultraviolet) lithography has drawn much attention as one essential technology for manufacturing a next generation semiconductor device. That is, for the production of next-generation semiconductor devices, EUV lithography has garnered significant attention as a crucial technology. The EUV lithography is a pattern-forming technology using an EUV ray having a wavelength of 13.5 nm as an exposure light source. According to the EUV lithography, an extremely fine pattern (e.g., less than or equal to 20 nm) may be formed in an exposure process during a manufacture of a semiconductor device (e.g., a semiconductor chip).

The extreme ultraviolet (EUV) lithography is realized through development of compatible photoresists which may be performed at a spatial resolution of less than or equal to 16 nm. Currently, efforts to alleviate insufficient specifications of chemically amplified (CA) photoresists such as a resolution, a photospeed, and feature roughness (or also referred to as a line edge roughness or LER) for the next generation device are being made.

An intrinsic image blurring due to an acid catalyzed reaction in these polymer-type or kind photoresists limits a resolution in small feature sizes, which has existed in electron beam (e-beam) lithography for a long time. The chemically amplified (CA) photoresists are designed for high sensitivity, but because their typical elemental makeups reduce light absorbance of the photoresists at a wavelength of 13.5 nm, it may decrease their sensitivity, and the chemically amplified (CA) photoresists may have more difficulties under an EUV exposure.

In addition, the CA photoresists may have difficulties in the small feature sizes due to roughness issues, and line edge roughness (LER) of the CA photoresists experimentally may be increased, as a photospeed may be decreased partially due to an essence of acid catalyst processes. Accordingly, a novel high-performance photoresist is desired or required in a semiconductor industry because of these defects and problems of the CA photoresists.

In order to overcome the aforementioned drawbacks of the chemically amplified (CA) organic photosensitive composition, an inorganic photosensitive composition has been researched. The inorganic photosensitive composition has been mainly or predominantly used for negative tone patterning which has resistance against removal by a developer composition due to chemical modification through nonchemical amplification mechanism. The inorganic composition contains an inorganic element that has a higher EUV absorption rate than hydrocarbon, and thus may secure sensitivity through the non-chemical amplification mechanism and may be less sensitive about a stochastic effect and thus may have low line edge roughness and small number of defects.

Inorganic photoresists based on peroxopolyacids of tungsten mixed with tungsten, niobium, titanium, and/or tantalum have been reported as radiation sensitive materials for patterning.

These materials are effective for patterning large pitches for bilayer configuration as far ultraviolet (deep UV), X-ray, and electron beam sources. When cationic hafnium metal oxide sulfate (HfSOx) materials along with a peroxo complexing agent was used to image a 15 nm half-pitch (HP) through projection EUV exposure, improved performance has been obtained. This system exhibits a high performance of a non-CA photoresist and has a practicable photospeed near to a requirement for an EUV photoresist. However, the hafnium metal oxide sulfate material having the peroxo complexing agent has some practical drawbacks. First, these materials are coated in a mixture of corrosive sulfuric acid/hydrogen peroxide and have insufficient shelf-life stability. Second, a structural change of the materials for performance improvement as a composite mixture is challenging. Third, development should be performed in a TMAH (tetramethylammonium hydroxide) solution at an extremely high concentration of 25 wt % and/or the like.

To address these issues, research has been focused on developing molecules that contain tin, which have excellent or suitable absorption of extreme ultraviolet rays. As for an organotin polymer among the molecules containing tin, alkyl ligands are dissociated by light absorption or secondary electrons produced. The dissociated alkyl ligands are then crosslinked with adjacent chains through oxo bonds and thus, enable the negative tone patterning which may not be removed by an organic developer. Although this organotin polymer exhibits greatly improved sensitivity as well as maintains a resolution and line edge roughness, the patterning characteristics need to be further improved for commercial availability.

### SUMMARY

One or more aspects of embodiments of the present disclosure are directed toward a semiconductor photoresist composition having excellent or suitable coating properties and line edge roughness (LER).

One or more aspects of embodiments of the present disclosure are directed toward a method of forming patterns using the semiconductor photoresist composition.

Additional aspects will be set forth in part in the description which follows and, in part, will be apparent from the description, or may be learned by practice of the presented embodiments of the disclosure.

According to one or more embodiments of the present disclosure, a semiconductor photoresist composition includes a first organometallic compound represented by Chemical Formula 1, a second organometallic compound represented by Chemical Formula 2, and a solvent.

(R¹)ₐ-M¹-X¹_{b} Chemical Formula 1

(R²)_{c}-M²-X²_{d} Chemical Formula 2

In Chemical Formula 1 and Chemical Formula 2,
M¹ and M² may each independently be tin (Sn) or tellurium (Te),
R¹ may be a substituted or unsubstituted C1 to C20 alkyl group, a substituted or unsubstituted C2 to C20 alkenyl group, a substituted or unsubstituted C2 to C20 alkynyl group, or -L^{a}-O—R^{a} (wherein L^{a} is a single bond or a substituted or unsubstituted C1 to C20 alkylene group, and R^{a} is a substituted or unsubstituted C1 to C20 alkyl group),
R² may be a substituted or unsubstituted C3 to C20 cycloalkyl group, a substituted or unsubstituted C2 to C20 heterocycloalkyl group, a substituted or unsubstituted C6 to C30 aryl group, or a substituted or unsubstituted C2 to C30 heteroaryl group,
X¹ and X² may each independently be selected from among an alkoxy or aryloxy group (—OR^{b}, wherein R^{b} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, or a (e.g., any suitable) combination thereof), a carboxyl group (—O(CO)R^{c}, wherein R^{c} may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, or a (e.g., any suitable) combination thereof), an alkylamido or dialkylamido group (—NR^{d}R^{e}, wherein R^{d} and R^{e} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, or a (e.g., any suitable) combination thereof), an amidato group (—NR^{f}(COR^{g}), wherein R^{f} and R^{g} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, or a (e.g., any suitable) combination thereof), an amidinato group (—NR^{h}C(NRⁱ)R^{j}, wherein R^{h}, Rⁱ, and R^{j} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, or a (e.g., any suitable) combination thereof), an alkylthio or arylthiol group (—SR^{k}, wherein R^{k} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, or a (e.g., any suitable) combination thereof), and a thiocarboxyl group (—S(CO)R^{l}, wherein R^{l} may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, or a (e.g., any suitable) combination thereof),
a, b, c, and d may each independently be an integer of 1 to 5,
a+b is an integer of 4 or 6, and
c+d is an integer of 4 or 6.

According to one or more embodiments, a method of forming patterns includes forming an etching-objective layer (e.g., etching-target layer) on a substrate, coating the semiconductor photoresist composition on the etching-objective layer to form a photoresist layer, patterning the photoresist layer to form a photoresist pattern, and etching the etching-objective layer using the photoresist pattern as an etching mask.

The semiconductor photoresist composition according to one or more embodiments may provide a photoresist pattern with excellent or suitable coating properties and LER.

### BRIEF DESCRIPTION OF DRAWINGS

The above and other aspects, features, and advantages of certain embodiments of the disclosure will be more apparent from the following description taken in conjunction with the accompanying drawings, in which:

FIGS. 1A-1E are cross-sectional views for illustrating a method of forming patterns using a semiconductor photoresist composition according to one or more embodiments of the present disclosure.

### DETAILED DESCRIPTION

The present disclosure may be modified in many alternate forms, and thus specific embodiments will be exemplified in the drawing and described in more detail. It should be understood, however, that it is not intended to limit the present disclosure to the particular forms disclosed, but rather, is intended to cover all modifications, equivalents, and alternatives falling within the spirit and scope of the present disclosure.

Hereinafter, referring to the drawings, example embodiments of the present disclosure are described in more detail. In the following description of the present disclosure, the well-established functions or constructions will not be described in order to make the present disclosure concise.

In order to clearly illustrate the present disclosure, the unessential description and relationships are omitted, and throughout the disclosure, the same or similar configuration elements are designated by the same reference numerals. Also, because the size and thickness of each configuration shown in the drawing are shown for better understanding and ease of description, the present disclosure is not necessarily limited thereto.

In the drawings, the thickness of layers, films, panels, regions, and/or the like, may be enlarged for clarity. In the drawings, the thickness of a part of layers or regions, and/or the like, may be exaggerated for clarity. It will be understood that if (e.g., when) an element such as a layer, film, region, or substrate is referred to as being “on” another element, it may be directly on the other element or intervening elements may also be present therebetween. In contrast, when an element is referred to as being “directly on” another element, there are no intervening elements present.

As used herein, “substituted” refers to replacement of a hydrogen by deuterium, a halogen, a hydroxyl group, a carboxyl group, a thiol group, a cyano group, a nitro group, —NRR′ (wherein, R and R′ may each independently be hydrogen, a substituted or unsubstituted C1 to C30 saturated or unsaturated aliphatic hydrocarbon group, a substituted or unsubstituted C3 to C30 saturated or unsaturated alicyclic hydrocarbon group, or a substituted or unsubstituted C6 to C30 aromatic hydrocarbon group), —SiRR′R″ (wherein, R, R′, and R″ may each independently be hydrogen, a substituted or unsubstituted C1 to C30 saturated or unsaturated aliphatic hydrocarbon group, a substituted or unsubstituted C3 to C30 saturated or unsaturated alicyclic hydrocarbon group, or a substituted or unsubstituted C6 to C30 aromatic hydrocarbon group), a C1 to C30 alkyl group, a C1 to C10 haloalkyl group, a C1 to C10 alkylsilyl group, a C3 to C30 cycloalkyl group, a C6 to C30 aryl group, a C1 to C20 alkoxy group, a C1 to C20 sulfide group, and/or a (e.g., any suitable) combination thereof. “Unsubstituted” refers to non-replacement of a hydrogen by another substituent and remaining of the hydrogen.

As used herein, if (e.g., when) a definition is not otherwise provided, the term “alkyl group” refers to a linear or branched aliphatic hydrocarbon group. The alkyl group may be a “saturated alkyl group” without any double bond or triple bond.

The alkyl group may be a C1 to C10 alkyl group. For example, the alkyl group may be a C1 to C8 alkyl group, a C1 to C7 alkyl group, a C1 to C6 alkyl group, or a C1 to C5 alkyl group. For example, the C1 to C5 alkyl group may be a methyl group, an ethyl group, a propyl group, an isopropyl group, an n-butyl group, an isobutyl group, a sec-butyl group, a tert-butyl group, or a 2,2-dimethylpropyl group.

As used herein, if (e.g., when) a definition is not otherwise provided, the term “cycloalkyl group” refers to a monovalent cyclic aliphatic hydrocarbon group.

The cycloalkyl group may be a C3 to C10 cycloalkyl group, for example, a C3 to C8 cycloalkyl group, a C3 to C7 cycloalkyl group, or a C3 to C6 cycloalkyl group. For example, the cycloalkyl group may be a cyclopropyl group, a cyclobutyl group, a cyclopentyl group, or a cyclohexyl group, but the present disclosure is not limited thereto.

As used herein, the term “aryl group” refers to a substituent in which all atoms in the cyclic substituent have a p-orbital and these p-orbitals are conjugated and may include a monocyclic or fused ring polycyclic functional group (i.e., rings sharing adjacent pairs of carbon atoms).

As used herein, unless otherwise defined, the term “alkenyl group” refers to an aliphatic unsaturated alkenyl group including at least one carbon-carbon double bond as a linear or branched aliphatic hydrocarbon group.

As used herein, unless otherwise defined, the term “alkynyl group” refers to an aliphatic unsaturated alkynyl group including at least one carbon-carbon triple bond as a linear or branched aliphatic hydrocarbon group.

In the chemical formulas described herein, t-Bu refers to a tert-butyl group.

Hereinafter, a semiconductor photoresist composition according to one or more embodiments will be described in more detail.

The semiconductor photoresist composition according to one or more embodiments includes a first organometallic compound represented by Chemical Formula 1, a second organometallic compound represented by Chemical Formula 2, and a solvent.

(R¹)ₐ-M¹-X¹_{b} Chemical Formula 1

(R²)_{c}-M²-X²_{d} Chemical Formula 2

In Chemical Formula 1 and Chemical Formula 2,
M¹ and M² may each independently be Sn or Te,
R¹ may be a substituted or unsubstituted C1 to C20 alkyl group, a substituted or unsubstituted C2 to C20 alkenyl group, a substituted or unsubstituted C2 to C20 alkynyl group, or -L^{a}-O—R^{a} (wherein L^{a} is a single bond or a substituted or unsubstituted C1 to C20 alkylene group, and R^{a} is a substituted or unsubstituted C1 to C20 alkyl group),
R² may be a substituted or unsubstituted C3 to C20 cycloalkyl group, a substituted or unsubstituted C2 to C20 heterocycloalkyl group, a substituted or unsubstituted C6 to C30 aryl group, or a substituted or unsubstituted C2 to C30 heteroaryl group,
X¹ and X² may each independently be selected from among an alkoxy or aryloxy group (—OR^{b}, wherein R^{b} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, or a (e.g., any suitable) combination thereof), a carboxyl group (—O(CO)R^{c}, wherein R^{c} may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, or a (e.g., any suitable) combination thereof), an alkylamido or dialkylamido group (—NR^{d}R^{e}, wherein R^{d} and R^{e} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, or a (e.g., any suitable) combination thereof), an amidato group (—NR^{f}(COR^{g}), wherein R^{f} and R^{g} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, or a (e.g., any suitable) combination thereof), an amidinato group (—NR^{h}C(NRⁱ)R^{j}, wherein R^{h}, Rⁱ, and R^{j} may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, or a (e.g., any suitable) combination thereof), an alkylthio or arylthiol group (—SR^{k}, wherein R^{k} may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, or a (e.g., any suitable) combination thereof), and a thiocarboxyl group (—S(CO)R^{l}, R^{l} may be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, or a (e.g., any suitable) combination thereof),
a, b, c, and d may each independently be an integer of 1 to 5,
a+b is an integer of 4 or 6, and
c+d is an integer of 4 or 6.

In the present disclosure, two types (kinds) of organometallic compounds, a first organometallic compound and a second organometallic compound with high EUV absorbance are blended to ensure stability against moisture and heat without additional organic additives, and crystallinity through the introduction of one or more suitable ligands are reduced to achieve excellent or suitable coating properties and LER.

For example, in the embodiment of chain-type or kind organometallic compounds with a substantially uniform structure, they may not be coated uniformly due to high crystallinity during coating. However, if (e.g., when) cyclic organometallic compounds are mixed as in the present disclosure, it is difficult to form crystals during coating, which may improve coating properties. That is, using only chain-like organometallic compounds, achieving uniform coating is difficult due to crystallization tendencies, whereas adding cyclic organometallic compounds may (e.g., should) prevent crystal formation and improve coating uniformity

For example, in one or more embodiments, the first organometallic compound and the second organometallic compound may be included in a weight ratio of about 90:10 to about 40:60.

In one or more embodiments, the first organometallic compound and the second organometallic compound may be included in a weight ratio of about 80:20 to about 40:60, for example, about 70:30 to about 40:60.

In one or more embodiments, R¹ may be a substituted or unsubstituted C1 to C10 alkyl group, a substituted or unsubstituted C2 to C10 alkenyl group, a substituted or unsubstituted C2 to C10 alkynyl group, or -L^{a}-O—R^{a} (wherein L^{a} is a single bond or a substituted or unsubstituted C1 to C20 alkylene group, and R^{a} is a substituted or unsubstituted C1 to C20 alkyl group),

R² may be a substituted or unsubstituted C3 to C10 cycloalkyl group, a substituted or unsubstituted C2 to C10 heterocycloalkyl group, a substituted or unsubstituted C6 to C20 aryl group, or a substituted or unsubstituted C2 to C20 heteroaryl group, and

X¹ and X² may each independently be selected from among an alkoxy or aryloxy group (—OR^{b}, wherein R^{b} may be a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, a substituted or unsubstituted C7 to C20 arylalkyl group, or a (e.g., any suitable) combination thereof), a carboxyl group (—O(CO)R^{c}, wherein R^{c} may be hydrogen, a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, a substituted or unsubstituted C7 to C20 arylalkyl group, or a (e.g., any suitable) combination thereof), an alkylamido or dialkylamido group (—NR^{d}R^{e}, wherein R^{d} and R^{e} may each independently be hydrogen, a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, a substituted or unsubstituted C7 to C20 arylalkyl group, or a (e.g., any suitable) combination thereof), an amidato group (—NR^{f}(COR^{g}), wherein R^{f} and R^{g} may each independently be hydrogen, a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, a substituted or unsubstituted C7 to C20 arylalkyl group, or a (e.g., any suitable) combination thereof), an amidinato group (—NR^{h}C(NRⁱ)R^{j}, wherein R^{h}, Rⁱ, and R^{j} may each independently be hydrogen, a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, a substituted or unsubstituted C7 to C20 arylalkyl group, or a (e.g., any suitable) combination thereof), an alkylthio or arylthiol group (—SR^{k}, wherein R^{k} may be a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, a substituted or unsubstituted C7 to C20 arylalkyl group, or a (e.g., any suitable) combination thereof), and a thiocarboxyl group (—S(CO)R^{l}, wherein R^{l} may be hydrogen, a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, a substituted or unsubstituted C7 to C20 arylalkyl group, or a (e.g., any suitable) combination thereof).

In one or more embodiments, R¹ may be a substituted or unsubstituted methyl group, a substituted or unsubstituted ethyl group, a substituted or unsubstituted propyl group, a substituted or unsubstituted butyl group, a substituted or unsubstituted isopropyl group, a substituted or unsubstituted tert-butyl group, a substituted or unsubstituted 2,2-dimethylpropyl group, a substituted or unsubstituted tert-pentyl group, a substituted or unsubstituted ethenyl group, a substituted or unsubstituted propenyl group, a substituted or unsubstituted butenyl group, a substituted or unsubstituted ethynyl group, a substituted or unsubstituted propynyl group, a substituted or unsubstituted butynyl group, a substituted or unsubstituted benzyl group, a substituted or unsubstituted methoxy group, a substituted or unsubstituted ethoxy group, a substituted or unsubstituted propoxy group, or a (e.g., any suitable) combination thereof,
R² may be a substituted or unsubstituted cyclopropyl group, a substituted or unsubstituted cyclobutyl group, a substituted or unsubstituted cyclopentyl group, a substituted or unsubstituted cyclohexyl group, a substituted or unsubstituted phenyl group, a substituted or unsubstituted naphthyl group, a substituted or unsubstituted anthracenyl group, a substituted or unsubstituted tolyl group, a substituted or unsubstituted xylene group, a substituted or unsubstituted pyridine group, a substituted or unsubstituted pyrrolidine group, a substituted or unsubstituted piperidine group, a substituted or unsubstituted pyrrolyl group, a substituted or unsubstituted furanyl (furyl) group, a substituted or unsubstituted tetrahydrofuranyl group, a substituted or unsubstituted pyranyl group, a substituted or unsubstituted tetrahydropyranyl group, a substituted or unsubstituted dioxane group, a substituted or unsubstituted morpholine group, or a (e.g., any suitable) combination thereof,
R^{b} may be a substituted or unsubstituted methyl group, a substituted or unsubstituted ethyl group, a substituted or unsubstituted propyl group, a substituted or unsubstituted butyl group, a substituted or unsubstituted isopropyl group, a substituted or unsubstituted tert-butyl group, substituted or unsubstituted tert-pentyl group, a substituted or unsubstituted 2,2-dimethylpropyl group, a substituted or unsubstituted cyclopropyl group, a substituted or unsubstituted cyclobutyl group, a substituted or unsubstituted cyclopentyl group, a substituted or unsubstituted cyclohexyl group, a substituted or unsubstituted ethenyl group, a substituted or unsubstituted propenyl group, a substituted or unsubstituted butenyl group, a substituted or unsubstituted ethynyl group, a substituted or unsubstituted propynyl group, a substituted or unsubstituted butynyl group, a substituted or unsubstituted phenyl group, a substituted or unsubstituted tolyl group, a substituted or unsubstituted xylene group, a substituted or unsubstituted benzyl group, or a (e.g., any suitable) combination thereof, and
R^{c}, R^{d}, R^{e}, R^{f}, R^{g}, R^{h}, Rⁱ, R^{j}, R^{k}, and R^{l} may each independently be hydrogen, a substituted or unsubstituted methyl group, a substituted or unsubstituted ethyl group, a substituted or unsubstituted propyl group, a substituted or unsubstituted butyl group, a substituted or unsubstituted isopropyl group, a substituted or unsubstituted tert-butyl group, a substituted or unsubstituted tert-pentyl group, a substituted or unsubstituted 2,2-dimethylpropyl group, a substituted or unsubstituted cyclopropyl group, a substituted or unsubstituted cyclobutyl group, a substituted or unsubstituted cyclopentyl group, a substituted or unsubstituted cyclohexyl group, a substituted or unsubstituted ethenyl group, a substituted or unsubstituted propenyl group, a substituted or unsubstituted butenyl group, a substituted or unsubstituted ethynyl group, a substituted or unsubstituted propynyl group, a substituted or unsubstituted butynyl group, a substituted or unsubstituted phenyl group, a substituted or unsubstituted tolyl group, a substituted or unsubstituted xylene group, a substituted or unsubstituted benzyl group, or a (e.g., any suitable) combination thereof.

In one or more embodiments, the second organometallic compound may be any one selected from among compounds listed in Group 2.

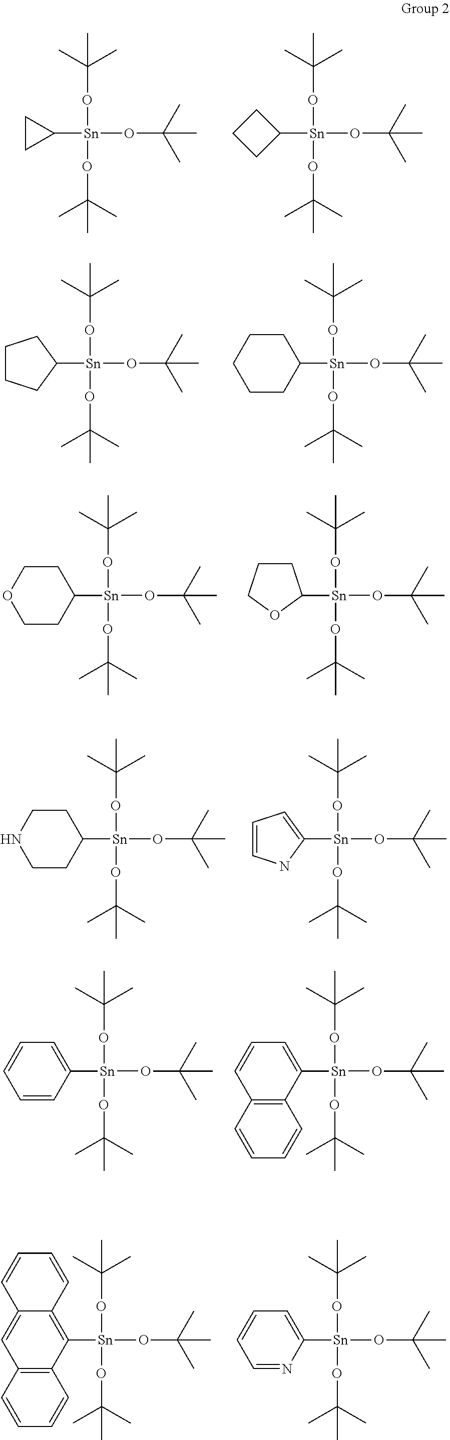

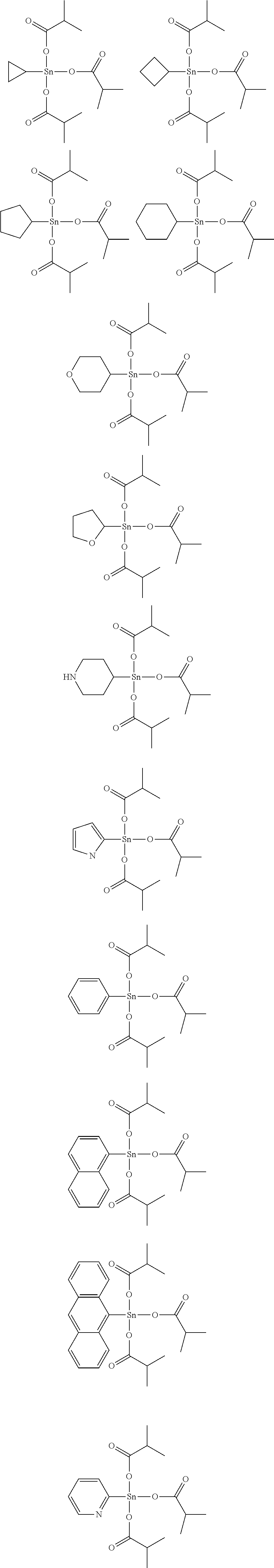

The first organometallic compound may be any one selected from among compounds listed in Group 1.

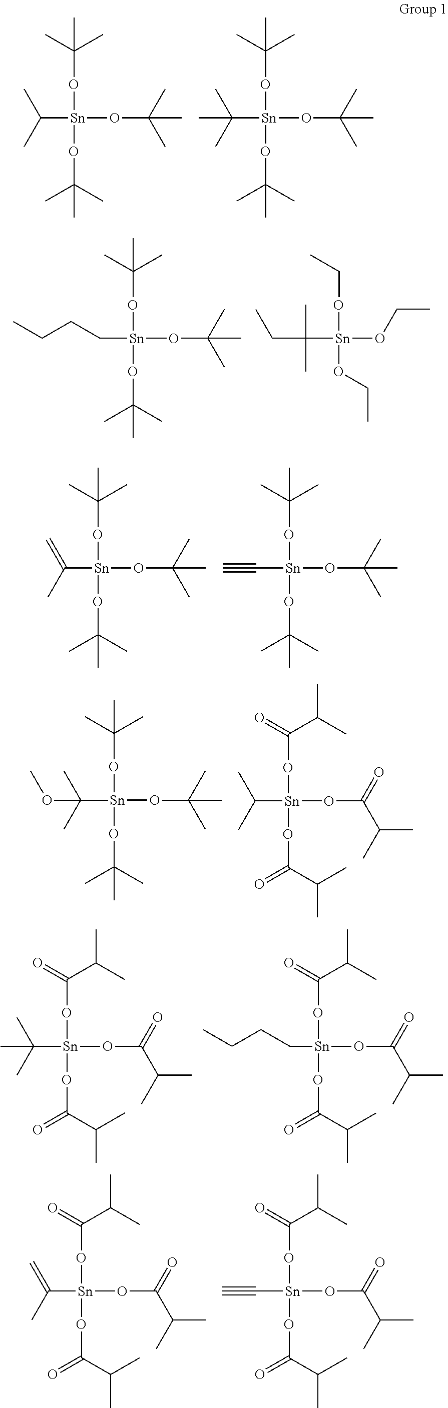

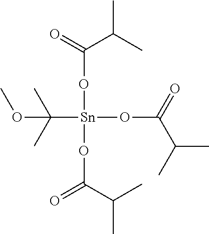 [SMILES: CO[C](C)(C)[Sn]([O]C(=O)C(C)C)([O]C(=O)C(C)C)[O]C(=O)C(C)C]

The organometallic compound strongly absorbs extreme ultraviolet light at 13.5 nm and may have excellent or suitable sensitivity to high-energy light.

In the semiconductor photoresist composition according to one or more embodiments, the first organometallic compound and the second organometallic compound may be each added in an amount of about 1 wt % to about 30 wt %, for example, about 1 wt % to about 25 wt %, for example, about 1 wt % to about 20 wt %, for example, about 1 wt % to about 15 wt %, for example, about 1 wt % to about 10 wt %, or for example, about 1 wt % to about 5 wt %, based on 100 wt % of a total weight of the semiconductor photoresist composition. If the organometallic compounds are each included in an amount within the above range, the storage stability and etch resistance of the semiconductor photoresist composition are improved, and the resolution characteristics are improved.

The semiconductor photoresist composition according to one or more embodiments includes the aforementioned first organometallic compound and the second organometallic compound, thereby providing the semiconductor photoresist composition having excellent or suitable sensitivity and pattern formation properties.

The solvent of the semiconductor photoresist composition according to one or more embodiments may be an organic solvent, and may be, for example, selected from aromatic compounds (e.g., xylene, toluene, and/or the like), alcohols (e.g., 4-methyl-2-pentanol, 4-methyl-2-propanol, 1-butanol, methanol, isopropyl alcohol, 1-propanol), ethers (e.g., anisole, tetrahydrofuran), esters (n-butyl acetate, propylene glycol monomethyl ether acetate, ethyl acetate, ethyl lactate), ketones (e.g., methyl ethyl ketone, 2-heptanone), and/or a (e.g., any suitable)mixture thereof, but the present disclosure is not limited thereto.

In one or more embodiments, the semiconductor photoresist composition may further include a resin in addition to the aforementioned first organometallic compound, second organometallic compound, and solvent.

The resin may be a phenol-based resin including at least one aromatic moiety selected moieties of Group 3.

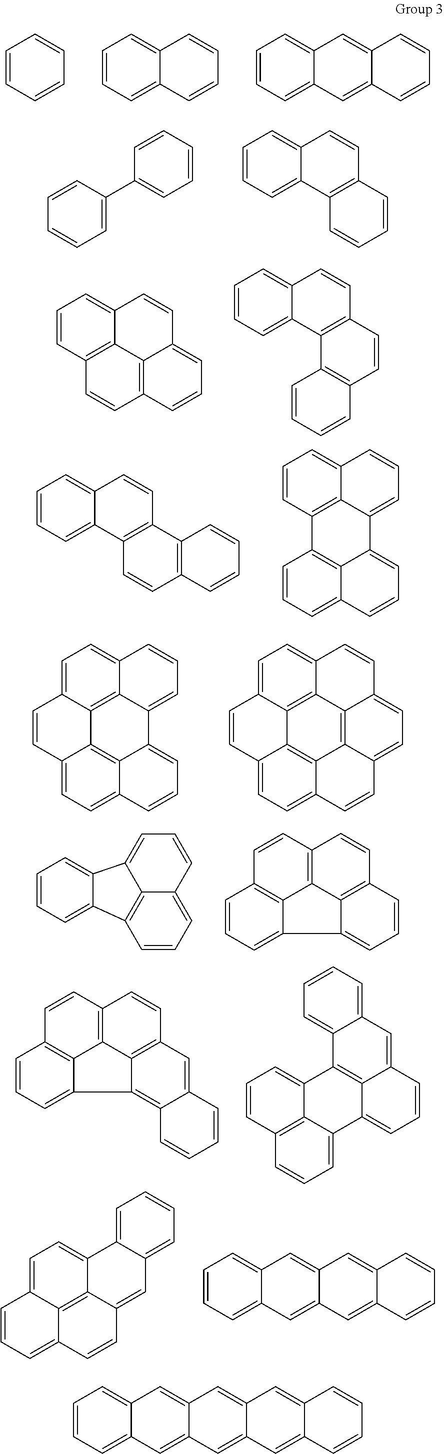

The resin may have a weight average molecular weight of about 500 to about 20,000.

In one or more embodiments, the resin may be included in an amount of about 0.1 wt % to about 50 wt % based on 100 wt % of a total amount of the semiconductor photoresist composition.

When the resin is included in the above content (e.g., amount) range, it may have excellent or suitable etch resistance and heat resistance.

In addition, the semiconductor photoresist composition according to one or more embodiments may include (e.g., consist of) the aforementioned first organometallic compound, second organometallic compound, solvent, and resin. In present disclosure, the semiconductor photoresist composition according to one or more embodiments may further include one or more additives as needed. Non-limiting examples of the additives may be a surfactant, a crosslinking agent, a leveling agent, an organic acid, a quencher, and/or a (e.g., any suitable) combination thereof.

The surfactant may include, for example, an alkyl benzene sulfonate salt, an alkyl pyridinium salt, polyethylene glycol, a quaternary ammonium salt, and/or a (e.g., any suitable) combination thereof, but embodiments of the present disclosure are not limited thereto.

The crosslinking agent may be, for example, a melamine-based crosslinking agent, a substituted urea-based crosslinking agent, an acryl-based crosslinking agent, an epoxy-based crosslinking agent, or a polymer-based crosslinking agent, but embodiments of the present disclosure are not limited thereto. It may be a crosslinking agent having at least two crosslinking forming substituents, for example, a compound such as methoxymethylated glycoluril, butoxymethylated glycoluril, methoxymethylated melamine, butoxymethylated melamine, methoxymethylated benzoguanamine, butoxymethylated benzoguanamine, 4-hydroxybutyl acrylate, acrylic acid, urethane acrylate, acryl methacrylate, 1,4-butanediol diglycidyl ether, glycidol, diglycidyl 1,2-cyclohexane dicarboxylate, trimethylpropane triglycidyl ether, 1,3-bis(glycidoxypropyl)tetramethyldisiloxane, methoxymethylated urea, butoxymethylated urea, methoxymethylated thiourea, and/or the like.

The leveling agent may be used for improving coating flatness during printing and may be a commercially available suitable leveling agent.

The organic acid may include p-toluenesulfonic acid, benzenesulfonic acid, p-dodecylbenzenesulfonic acid, 1,4-naphthalenedisulfonic acid, methanesulfonic acid, a fluorinated sulfonium salt, malonic acid, citric acid, propionic acid, methacrylic acid, oxalic acid, lactic acid, glycolic acid, succinic acid, and/or a (e.g., any suitable) combination thereof, but embodiments of the present disclosure are not limited thereto.

The quencher may be diphenyl (p-tolyl) amine, methyl diphenyl amine, triphenyl amine, phenylenediamine, naphthylamine, diaminonaphthalene, or a (e.g., any suitable) combination thereof.

A amount of the additives included in the semiconductor photoresist composition may be controlled or selected depending on desired or suitable properties.

In one or more embodiments, the semiconductor photoresist composition may further include a silane coupling agent as an adherence enhancer in order to improve a close-contacting force with the substrate (e.g., in order to improve adherence of the semiconductor photoresist composition to the substrate). The silane coupling agent may be, for example, a silane compound including a carbon-carbon unsaturated bond such as vinyltrimethoxysilane, vinyl triethoxysilane, vinyl trichlorosilane, vinyl tris(β-methoxyethoxy)silane, or 3-methacryloxypropyltrimethoxysilane, 3-acryloxypropyltrimethoxysilane, p-styryl trimethoxysilane, 3-methacryloxypropylmethyldimethoxysilane, 3-methacryloxypropylmethyl diethoxysilane; trimethoxy[3-(phenylamino)propyl]silane; and/or the like, but embodiments of the present disclosure are not limited thereto.

The semiconductor photoresist composition may be formed into a pattern having a high aspect ratio without a collapse. Accordingly, in order to form a fine pattern having a width (e.g., line width) of, for example, about 5 nm to about 100 nm, for example, about 5 nm to about 80 nm, for example, about 5 nm to about 70 nm, for example, about 5 nm to about 50 nm, for example, about 5 nm to about 40 nm, for example, about 5 nm to about 30 nm, for example, about 5 nm to about 20 nm, or for example, about 5 nm to about 10 nm, the semiconductor photoresist composition may be used for a photoresist process using light in a wavelength in a range of about 5 nm to about 150 nm, for example, about 5 nm to about 100 nm, about 5 nm to about 80 nm, about 5 nm to about 50 nm, about 5 nm to about 30 nm, or about 5 nm to about 20 nm. Accordingly, the semiconductor photoresist composition according to one or more embodiments may be used to realize extreme ultraviolet lithography using an EUV light source of a wavelength of about 13.5 nm.

According to one or more embodiments, a method of forming patterns using the aforementioned semiconductor photoresist composition is provided. For example, the manufactured pattern may be a photoresist pattern.

The method of forming patterns according to one or more embodiments includes forming an etching-objective layer (e.g., etching-target layer) on a substrate, coating the semiconductor photoresist composition on the etching-objective layer to form a photoresist layer, patterning the photoresist layer to form a photoresist pattern, and etching the etching-objective layer using the photoresist pattern as an etching mask.

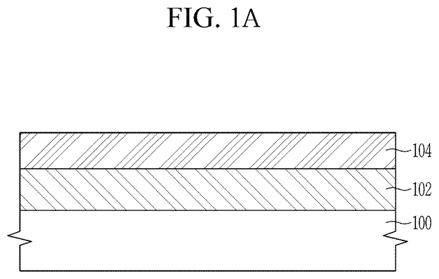

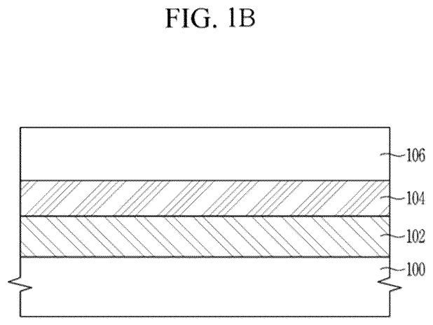

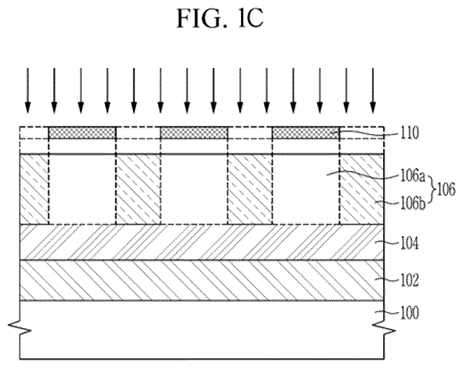

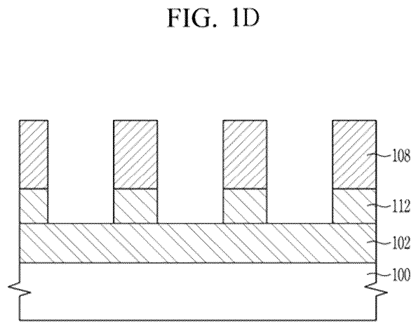

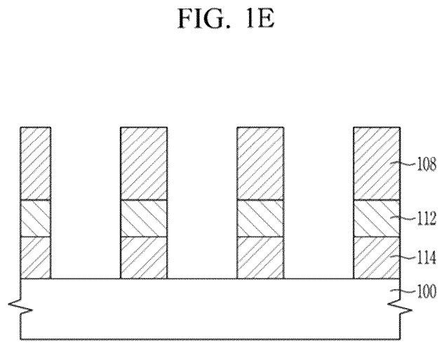

Hereinafter, a method of forming patterns using the semiconductor photoresist composition will be described in more detail by referring to FIGS. 1A-1E. FIGS. 1A-1E are cross-sectional views for illustrating a method of forming patterns using a semiconductor photoresist composition according to one or more embodiments.

Referring to FIG. 1A, an object for etching (e.g., etching-objective layer or etching-target layer) is prepared. The object for etching may be a thin film 102 formed on a semiconductor substrate 100. Hereinafter, the object for etching is limited to the thin film 102. A surface of the thin film 102 is washed to remove impurities and/or the like remaining thereon. The thin film 102 may be, for example, a silicon nitride layer, a polysilicon layer, or a silicon oxide layer.

Subsequently, a resist underlayer composition for providing a resist underlayer 104 is spin-coated on the surface of the washed thin film 102. However, embodiments of the present disclosure are not limited thereto, and one or more suitable coating methods, for example, a spray coating, a dip coating, a knife edge coating, a printing method (for example, an inkjet printing and/or a screen printing), and/or the like may be used.

In one or more embodiments, the coating process of the resist underlayer may not be provided, and hereinafter, a process including a coating of the resist underlayer is described.

Then, the coated resist underlayer composition is dried and baked to form a resist underlayer 104 on the thin film 102. The baking may be performed at about 100° C. to about 500° C., for example, about 100° C. to about 300° C.

The resist underlayer 104 is formed between the substrate 100 and a photoresist layer 106 and thus may prevent or reduce non-uniformity and pattern formability of a photoresist line width if (e.g., when) a ray reflected from on the interface between the substrate 100 and the photoresist layer 106 or a hardmask between layers is scattered into an unintended photoresist region.

Referring to FIG. 1B, the photoresist layer 106 is formed by coating the semiconductor photoresist composition on the resist underlayer 104. The photoresist layer 106 is obtained by coating the aforementioned semiconductor photoresist composition on the thin film 102 formed on the substrate 100 and then, curing it through a heat treatment.

In one or more embodiments, the formation of a pattern by using the semiconductor photoresist composition may include coating the semiconductor resist composition on the substrate 100 having the thin film 102 through spin coating, slit coating, inkjet printing, and/or the like and then, drying it to form the photoresist layer 106.

The semiconductor photoresist composition has already been illustrated in detail and will not be illustrated again.

Subsequently, the substrate 100 having the photoresist layer 106 is subjected to a first baking (thermal treatment) process. The first baking process may be performed at about 80° C. to about 120° C.

Referring to FIG. 1C, the photoresist layer 106 may be selectively exposed using a patterned mask 110.

For example, the exposure may use an activation radiation with light having a high energy wavelength such as EUV (extreme ultraviolet; a wavelength of about 13.5 nm), an E-Beam (an electron beam), and/or the like as well as a short wavelength such as an i-line (a wavelength of about 365 nm), a KrF excimer laser (a wavelength of about 248 nm), an ArF excimer laser (a wavelength of about 193 nm), and/or the like.

For example, light or exposure beam for the exposure according to one or more embodiments may have a short wavelength in a range of about 5 nm to about 150 nm, and/or a high energy wavelength, for example, may be an EUV (extreme ultraviolet; a wavelength of 13.5 nm), and/or may be an E-Beam (an electron beam), and/or the like.

The exposed region 106b of the photoresist layer 106 has a different solubility from the unexposed region 106a of the photoresist layer 106 by forming a polymer by a crosslinking reaction such as condensation between organometallic compounds.

Subsequently, the substrate 100 may be subjected to a second baking (thermal treatment) process. The second baking process may be performed at a temperature of about 90° C. to about 200° C. The exposed region 106b of the photoresist layer 106 may become indissoluble regarding a developer due to the second baking process.

In FIG. 1D, the unexposed region 106a of the photoresist layer is dissolved and removed using the developer to form a photoresist pattern 108. For example, the unexposed region 106a of the photoresist layer is dissolved and removed by using an organic solvent such as 2-heptanone and/or the like to complete the photoresist pattern 108 corresponding to a negative tone image.

As described above, a developer used in the method of forming patterns according to one or more embodiments may be an organic solvent. The organic solvent used in the method of forming patterns according to one or more embodiments may be, for example, a ketone such as methylethylketone, acetone, cyclohexanone, 2-heptanone, and/or the like, an alcohol such as 4-methyl-2-propanol, 1-butanol, isopropanol, 1-propanol, methanol, and/or the like, an ester such as propylene glycol monomethyl ether acetate, ethyl acetate, ethyl lactate, n-butyl acetate, butyrolactone, and/or the like, an aromatic compound such as benzene, xylene, toluene, and/or the like, or a (e.g., any suitable) combination thereof.

However, the photoresist pattern according to one or more embodiments is not necessarily limited to the negative tone image but may be formed to have a positive tone image. Herein, a developer used for forming the positive tone image may be a quaternary ammonium hydroxide composition such as tetraethylammonium hydroxide, tetrapropylammonium hydroxide, tetrabutylammonium hydroxide, or a (e.g., any suitable) combination thereof.

As described above, exposure to light having a high energy such as EUV (extreme ultraViolet; a wavelength of 13.5 nm), to an E-Beam (an electron beam), and/or the like and/or to light having a short wavelength such as i-line (wavelength of about 365 nm), KrF excimer laser (wavelength of about 248 nm), ArF excimer laser (wavelength of about 193 nm), and/or the like may provide a photoresist pattern 108 having a width of a thickness of about 5 nm to about 100 nm. For example, in one or more embodiment, the photoresist pattern 108 may have a width of a thickness of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, or about 5 nm to about 20 nm, or about 5 nm to about 10 nm.

In one or more embodiments, the photoresist pattern 108 may have a pitch (center-to-center distance between adjacent features in the pattern) having (with) a half-pitch of less than or equal to about 50 nm, for example less than or equal to about 40 nm, for example less than or equal to about 30 nm, for example less than or equal to about 20 nm, or for example less than or equal to about 10 nm, and a line width roughness of less than or equal to about 5 nm, less than or equal to about 3 nm, less than or equal to about 2 nm, or less than or equal to about 1 nm.

Subsequently, the photoresist pattern 108 is used as an etching mask to etch the resist underlayer 104. Through this etching process, an organic layer pattern 112 is formed. The organic layer pattern 112 also may have a width corresponding to that of the photoresist pattern 108.

Referring to FIG. 1E, the exposed thin film 102 is etched by applying the photoresist pattern 108 as an etching mask. As a result, the thin film is formed as a thin film pattern 114.

The etching of the thin film 102 may be, for example, dry etching using an etching gas, and the etching gas may be, for example, CHF₃, CF₄, Cl₂, BCl₃, or a mixed gas thereof.

In the exposure process, the thin film pattern 114 formed by using the photoresist pattern 108 formed through the exposure process performed by using an EUV light source may have a width corresponding to that of the photoresist pattern 108. For example, in one or more embodiments, the thin film pattern 114 may have a width (e.g., line width) of about 5 nm to about 100 nm which is equal to that of the photoresist pattern 108. For example, in one or more embodiments, the thin film pattern 114 formed by using the photoresist pattern 108 formed through the exposure process performed by using an EUV light source may have a width (e.g., line width) of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, or about 5 nm to about 20 nm, for example, a width (e.g., line width) of less than or equal to about 20 nm, like that of the photoresist pattern 108.

Hereinafter, the present disclosure will be described in more detail through examples of the preparation of the aforementioned semiconductor photoresist composition. However, the present disclosure is technically not restricted by the following examples.

### Synthesis of First Organometallic Compound

### Synthesis Example 1

In a 250 mL 2-necked round-bottomed flask, Ph₃SnCl (20 g, 51.9 mmol) was dissolved in 100 mL of anhydrous tetrahydrofuran (THF) and the temperature was lowered to 0° C. in an ice bath. Then, tert-butylmagnesium bromide 1 M THF solution (62.3 mmol) was slowly added in a dropwise fashion. After dropwise addition was completed, stirring was performed at 25° C. for 12 hours. After distillation under reduced pressure, 50 mL of isobutyric acid was slowly added in a dropwise fashion at 25° C. and heated to reflux for 12 hours. After lowering the temperature to 25° C., isobutyric acid was vacuum-distilled to obtain a compound represented by Chemical Formula 1a.

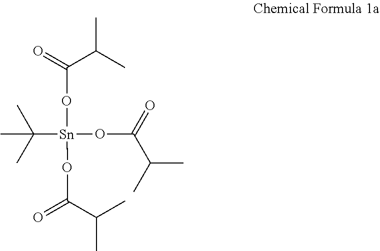 [SMILES: CC(C)C(=O)[O][Sn]([O]C(=O)C(C)C)([O]C(=O)C(C)C)[C](C)(C)C]

### Synthesis Example 2

In a 250 mL 2-necked round-bottomed flask, Ph₃SnCl (20 g, 51.9 mmol) was dissolved in 100 mL of anhydrous tetrahydrofuran (THF) and the temperature was lowered to 0° in an ice bath. Then, isopropyl magnesium bromide 1 M THF solution (62.3 mmol) was slowly added in a dropwise fashion. After dropwise addition was completed, stirring was performed at 25° C. for 12 hours. After distillation under reduced pressure, the resultant was dissolved in 50 mL of CH₂Cl₂, and 3 equivalents (155.7 mmol) of 2 M HCl diethyl ether solution was slowly added in a dropwise fashion at −78° C. for 30 minutes. After stirring for 12 hours at 25° C., the solvent was concentrated, vacuum-distilled, and then dissolved in 50 mL of CH₂Cl₂, 3 equivalents of silver tert-butoxide (51.9 mmol) was added in a dropwise fashion at 0° C., and the resulting solid was filtered. After filtering, the filtrate was distilled to obtain a compound represented by Chemical Formula 2a.

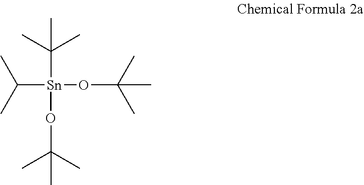 [SMILES: C[CH](C)[Sn]([O]C(C)(C)C)([O]C(C)(C)C)[C](C)(C)C]

### Synthesis Example 3

A compound represented by Chemical Formula 3a was obtained in substantially the same manner as in Synthesis Example 1, except that 1 M THF solution (62.3 mmol) of 1-propene-2-magnesium bromide was used instead of tert-butylmagnesium bromide.

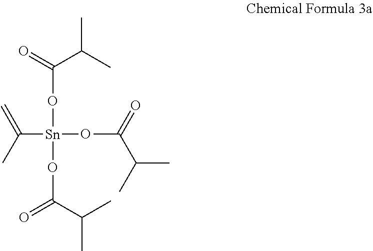 [SMILES: C=[C](C)[Sn]([O]C(=O)C(C)C)([O]C(=O)C(C)C)[O]C(=O)C(C)C]

### Synthesis of Second Organometallic Compound

### Synthesis Example 4

A compound represented by Chemical Formula 1b was obtained In substantially the same manner as in Synthesis Example 1, except that 1 M THF solution (62.3 mmol) of cyclopentylmagnesium bromide was used instead of tert-butylmagnesium bromide.

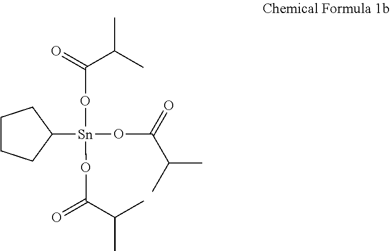 [SMILES: CC(C)C(=O)[O][Sn]([O]C(=O)C(C)C)([O]C(=O)C(C)C)[CH]1CCCC1]

### Synthesis Example 5

In a 250 mL 2-necked round-bottomed flask, Ph₃SnCl (20 g, 51.9 mmol) was dissolved in 100 mL of anhydrous tetrahydrofuran (THF) and the temperature was lowered to 0° C. in an ice bath. Then, cyclohexylmagnesium bromide 1 M THF solution (62.3 mmol) was slowly added in a dropwise fashion. After dropwise addition was completed, stirring was performed at 25° C. for 12 hours. After distillation under reduced pressure, the resultant was dissolved in 50 mL of CH₂Cl₂, and 3 equivalents (155.7 mmol) of 2 M HCl diethyl ether solution was slowly added in a dropwise fashion at −78° C. for 30 minutes. After stirring for 12 hours at 25° C., the solvent was concentrated, vacuum-distilled, and then dissolved in 50 mL of CH₂Cl₂, 3 equivalents of silver tert-butoxide (51.9 mmol) was added in a dropwise fashion at 0° C., and the resulting solid was filtered. After filtering, the filtrate was distilled to obtain a compound represented by Chemical Formula 2b.

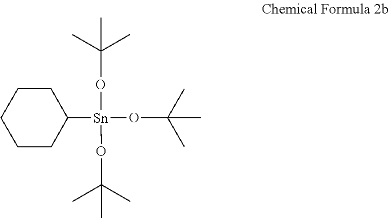 [SMILES: CC(C)(C)[O][Sn]([O]C(C)(C)C)([O]C(C)(C)C)[CH]1CCCCC1]

### Synthesis Example 6

In a 250 mL 2-necked round-bottomed flask, Sn(NEt₂)₄ (20 g, 49.1 mmol) was dissolved in 100 mL of anhydrous tetrahydrofuran (THF) and the temperature was lowered to −50° C. in an ice bath. Then, phenyllithium 1 M THF solution (10.0 mmol) was slowly added in a dropwise fashion. After dropwise addition was completed, stirring was performed at 25° C. for 12 hours. Excess isopropanol (100 mmol) was added at −50° C. and the temperature was gradually raised to room temperature. The solvent was removed by distillation under reduced pressure, and the remaining material was separated and purified under reduced pressure conditions to obtain phenyltin triisopropoxide (PhSn(OiPr)₃). 50 mL of anhydrous toluene was added thereto, and isobutyric acid was slowly added in a dropwise fashion at −20° C., heated to reflux for 2 hours, and then vacuum-distilled to obtain a compound represented by Chemical Formula 3b.

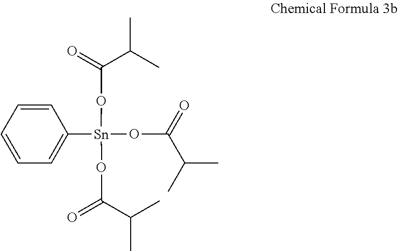 [SMILES: CC(C)C(=O)[O][Sn]([O]C(=O)C(C)C)([O]C(=O)C(C)C)[c]1ccccc1]

### Synthesis Example 7

In a 250 mL 2-necked round-bottomed flask, Sn(NEt₂)₄ (20 g, 49.1 mmol) was dissolved in 100 mL of anhydrous tetrahydrofuran (THF) and the temperature was lowered to −50° C. in an ice bath. Then, pyridine magnesium bromide 1 M THF solution (10.0 mmol) was slowly added in a dropwise fashion. After dropwise addition was completed, stirring was performed at 25° C. for 12 hours. Excess isopropanol (100 mmol) was added at −50° C. and the temperature was gradually raised to room temperature. The solvent was removed by distillation under reduced pressure, and the remaining material was separated and purified under reduced pressure conditions to obtain pyridine tin triisopropoxide (PySn(OiPr)₃). 50 mL of anhydrous toluene was added thereto, and isobutyric acid was slowly added in a dropwise fashion at −20° C., heated to reflux for 2 hours, and then vacuum-distilled to obtain a compound represented by Chemical Formula 4b.

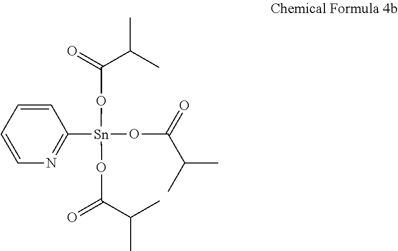 [SMILES: CC(C)C(=O)[O][Sn]([O]C(=O)C(C)C)([O]C(=O)C(C)C)[c]1ccccn1]

### Preparation of Semiconductor Photoresist Composition

### Examples 1 to 12 and Comparative Examples 1 to 7

According to Table 1, a pair of respective compounds selected from the compounds represented by Chemical Formula 1a, Chemical Formula 2a, Chemical Formula 3a, Chemical Formula 1 b, Chemical Formula 2b, Chemical Formula 3b, and Chemical Formula 4b obtained in Synthesis Examples 1 to 7 were dissolved at a concentration of 3 wt % in PGMEA (propylene glycol monomethyl ether acetate), filtered with a 0.1 μm PTFE syringe filter to prepare a corresponding photoresist composition.

### Evaluation 1: Evaluation of Coating Surface Roughness

Each of photoresist compositions of Examples 1 to 14, and Comparative Examples 1 to 7 was coated on a wafer, exposed on a hotplate at 100° C. for 60 seconds, and surface roughness (Rq) was measured using an AFM (atomic force microscope). These results were evaluated according to the following criteria and are shown in Table 1.

### Surface Roughness (Rq Value)

∘: less than or equal to 0.4
Δ: greater than 0.4 and less than or equal to 0.7
X: greater than 0.7

### Evaluation 2: Evaluation of Line Edge Roughness (LER)

A linear array of 50 circular pads with a diameter of 500 μm was projected on the wafer coated with one of the photoresist compositions of Examples 1 to 14 and Comparative Examples 1 and 7 by using EUV light (Lawrence Berkeley National Laboratory Micro Exposure Tool, MET). Herein, exposure time of the pads was adjusted to apply an increased EUV dose to each pad.

Subsequently, the resist and the substrate were exposed on a hot plate at 160° C. for 120 seconds and then, baked. The baked film was immersed in a developer (2-heptanone) for 30 seconds each, and then washed with the same developer for an additional 10 seconds to form a negative tone image, that is, to remove the unexposed portion of the coating. Finally, hot plate baking was performed at 150° C. for 2 minutes to complete the process.

Line edge roughness (LER) of line & space patterns was measured using an electron microscope. These results were evaluated according to the following criteria and are shown in Table 1.

### Line Edge Roughness (LER)

∘: less than or equal to 4 nm
Δ: greater than 4 nm and less than or equal to 7 nm
X: greater than 7 nm

TABLE 1

| | First | Second | | Surface | |
|---|---|---|---|---|---|
| | organometallic | organometallic | Weight | roughness | |
| | compound | compound | ratio | (Rq) | LER |
| Example 1 | Chemical | Chemical | 50:50 | ◯ | ◯ |
| | Formula 1a | Formula 1b | | | |
| Example 2 | Chemical | Chemical | 50:50 | Δ | ◯ |
| | Formula 1a | Formula 2b | | | |
| Example 3 | Chemical | Chemical | 50:50 | ◯ | ◯ |
| | Formula 1a | Formula 3b | | | |
| Example 4 | Chemical | Chemical | 50:50 | ◯ | ◯ |
| | Formula 1a | Formula 4b | | | |
| Example 5 | Chemical | Chemical | 50:50 | ◯ | ◯ |
| | Formula 2a | Formula 1b | | | |
| Example 6 | Chemical | Chemical | 50:50 | ◯ | ◯ |
| | Formula 2a | Formula 2b | | | |
| Example 7 | Chemical | Chemical | 50:50 | ◯ | ◯ |
| | Formula 2a | Formula 3b | | | |
| Example 8 | Chemical | Chemical | 50:50 | ◯ | ◯ |
| | Formula 2a | Formula 4b | | | |
| Example 9 | Chemical | Chemical | 50:50 | ◯ | Δ |
| | Formula 3a | Formula 1b | | | |
| Example | Chemical | Chemical | 50:50 | ◯ | ◯ |
| 10 | Formula 3a | Formula 2b | | | |
| Example | Chemical | Chemical | 50:50 | ◯ | Δ |
| 11 | Formula 3a | Formula 3b | | | |
| Example | Chemical | Chemical | 50:50 | ◯ | Δ |
| 12 | Formula 3a | Formula 4b | | | |
| Example | Chemical | Chemical | 80:20 | ◯ | ◯ |
| 13 | Formula 1a | Formula 1b | | | |
| Example | Chemical | Chemical | 60:40 | ◯ | ◯ |
| 14 | Formula 3a | Formula 1b | | | |
| Comparative | Chemical | — | 100:0 | X | Δ |
| Example 1 | Formula 1a | | | | |
| Comparative | Chemical | — | 100:0 | ◯ | X |
| Example 2 | Formula 2a | | | | |
| Comparative | Chemical | — | 100:0 | X | X |
| Example 3 | Formula 3a | | | | |
| Comparative | — | Chemical | 0:100 | X | X |
| Example 4 | | Formula 1b | | | |
| Comparative | — | Chemical | 0:100 | Δ | Δ |
| Example 5 | | Formula 2b | | | |
| Comparative | — | Chemical | 0:100 | X | Δ |
| Example 6 | | Formula 3b | | | |
| Comparative | — | Chemical | 0:100 | Δ | X |
| Example 7 | | Formula 4b | | | |

From the results in Table 1, each of the semiconductor photoresist compositions according to Examples exhibited reduced surface roughness compared to Comparative Examples, showing excellent or suitable coating properties and excellent or suitable line edge roughness. That is, the semiconductor photoresist compositions from the provided Examples each showed a decrease in surface roughness when compared to those from the Comparative Examples. This indicates that the compositions possess superior or appropriate coating qualities and exhibit excellent or appropriate line edge roughness.

As utilized herein, the terms “and/or” and “or” may include any and all combinations of one or more of the associated listed items. Expressions such as “at least one of,” when preceding a list of elements, modify the entire list of elements and do not modify the individual elements of the list.

It will be further understood that the terms “comprise”, “include,” or “have/has,” when utilized in the present disclosure, specify the presence of stated features, integers, steps, operations, elements, and/or components, but do not preclude the presence or addition of one or more other features, integers, steps, operations, elements, components, and/or groups thereof. The “/” utilized below may be interpreted as “and” or as “or” depending on the situation.

As utilized herein, the singular forms “a,” “an,” and “the” are intended to include the plural forms as well, unless the context clearly indicates otherwise. Further, the utilization of “may” when describing embodiments of the present disclosure refers to “one or more embodiments of the present disclosure”.

In the context of the present disclosure and unless otherwise defined, the terms “use,” “using,” and “used” may be considered synonymous with the terms “utilize,” “utilizing,” and “utilized,” respectively.

As utilized herein, the term “about,” or similar terms are used as terms of approximation and not as terms of degree, and are intended to account for the inherent deviations in measured or calculated values that would be recognized by those of ordinary skill in the art. “About” or “approximately,” as used herein, is also inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, or 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

A pattern forming device, a semiconductor forming device and/or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the present disclosure.

Hereinbefore, the certain example embodiments of the present disclosure have been described and illustrated, however, it is apparent to a person with ordinary skill in the art that the disclosure is not limited to the embodiments as described, and may be variously modified and transformed without departing from the spirit and scope of the present disclosure. Accordingly, the modified or transformed embodiments as such may not be understood separately from the technical ideas and aspects of the present disclosure, and the modified embodiments are within the scope of the claims and equivalents thereof, of the present disclosure.

### REFERENCE NUMERALS

| | |
|---|---|
| 100: substrate | 102: thin film |
| 104: resist underlayer | 106: photoresist layer |
| 106a: unexposed region | 106b: exposed region |
| 108: photoresist pattern | 112: organic layer pattern |
| 110: patterned mask | 114: thin film pattern |

What is claimed is:

1. A semiconductor photoresist composition, comprising:
a first organometallic compound represented by Chemical Formula 1;
a second organometallic compound represented by Chemical Formula 2; and
a solvent:
(R¹)ₐ-M¹-X¹_{b} Chemical Formula 1
(R²)_{c}-M²-X²_{d} Chemical Formula 2
wherein, in Chemical Formula 1 and Chemical Formula 2,
M¹ and M² are each independently Sn or Te,
R¹ is a substituted or unsubstituted C1 to C20 alkyl group, a substituted or unsubstituted C2 to C20 alkenyl group, a substituted or unsubstituted C2 to C20 alkynyl group, or -L^{a}-O—R^{a} (wherein L^{a} is a single bond or a substituted or unsubstituted C1 to C20 alkylene group, and R^{a} is a substituted or unsubstituted C1 to C20 alkyl group),
R² is a substituted or unsubstituted C3 to C20 cycloalkyl group, a substituted or unsubstituted C2 to C20 heterocycloalkyl group, a substituted or unsubstituted C6 to C30 aryl group, or a substituted or unsubstituted C2 to C30 heteroaryl group,
X¹ and X² are each independently selected from among an alkoxy or aryloxy group (—OR^{b}, wherein R^{b} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, or a combination thereof), a carboxyl group (—O(CO)R^{c}, wherein R^{c} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, or a combination thereof), an alkylamido or dialkylamido group (—NR^{d}R^{e}, wherein R^{d} and R^{e} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, or a combination thereof), an amidato group (—NR^{f}(COR^{g}), wherein R^{f} and R^{g} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, or a combination thereof), an amidinato group (—NR^{h}C(NRⁱ)R^{j}, wherein R^{h}, Rⁱ, and R^{j} are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, or a combination thereof), an alkylthio or arylthiol group (—SR^{k}, wherein R^{k} is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, or a combination thereof), and a thiocarboxyl group (—S(CO)R^{l}, wherein R^{l} is hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, a substituted or unsubstituted C7 to C30 arylalkyl group, or a combination thereof),
a, b, c, and d are each independently an integer of 1 to 5,
a+b is an integer of 4 or 6, and
c+d is an integer of 4 or 6.

2. The semiconductor photoresist composition as claimed in claim 1, wherein
the first organometallic compound and the second organometallic compound are in a weight ratio of about 90:10 to about 40:60.

3. The semiconductor photoresist composition as claimed in claim 1, wherein
the first organometallic compound and the second organometallic compound are in a weight ratio of about 80:20 to about 40:60.

4. The semiconductor photoresist composition as claimed in claim 1, wherein
R¹ is a substituted or unsubstituted C1 to C10 alkyl group, a substituted or unsubstituted C2 to C10 alkenyl group, a substituted or unsubstituted C2 to C10 alkynyl group, or -L^{a}-O—R^{a} (wherein L^{a} is a single bond or a substituted or unsubstituted C1 to C20 alkylene group, and R^{a} is a substituted or unsubstituted C1 to C20 alkyl group),
R² is a substituted or unsubstituted C3 to C10 cycloalkyl group, a substituted or unsubstituted C2 to C10 heterocycloalkyl group, a substituted or unsubstituted C6 to C20 aryl group, or a substituted or unsubstituted C2 to C20 heteroaryl group, and
X¹ and X² are each independently selected from among an alkoxy or aryloxy group (—OR^{b}, wherein R^{b} is a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, a substituted or unsubstituted C7 to C20 arylalkyl group, or a combination thereof), a carboxyl group (—O(CO)R^{c}, wherein R^{c} is hydrogen, a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, a substituted or unsubstituted C7 to C20 arylalkyl group, or a combination thereof), an alkylamido or dialkylamido group (—NR^{d}R^{e}, wherein R^{d} and R^{e} are each independently hydrogen, a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, a substituted or unsubstituted C7 to C20 arylalkyl group, or a combination thereof), an amidato group (—NR^{f}(COR^{g}), wherein R^{f} and R^{g} are each independently hydrogen, a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, a substituted or unsubstituted C7 to C20 arylalkyl group, or a combination thereof), an amidinato group (—NR^{h}C(NRⁱ)R^{j}, wherein R^{h}, Rⁱ, and R^{j} are each independently hydrogen, a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, a substituted or unsubstituted C7 to C20 arylalkyl group, or a combination thereof), an alkylthio or arylthiol group (—SR^{k}, wherein R^{k} is a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, a substituted or unsubstituted C7 to C20 arylalkyl group, or a combination thereof), and a thiocarboxyl group (—S(CO)R^{l}, wherein R^{l} is hydrogen, a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, a substituted or unsubstituted C7 to C20 arylalkyl group, or a combination thereof).

5. The semiconductor photoresist composition as claimed in claim 1, wherein
R¹ is a substituted or unsubstituted methyl group, a substituted or unsubstituted ethyl group, a substituted or unsubstituted propyl group, a substituted or unsubstituted butyl group, a substituted or unsubstituted isopropyl group, a substituted or unsubstituted tert-butyl group, a substituted or unsubstituted 2,2-dimethylpropyl group, a substituted or unsubstituted tert-pentyl group, a substituted or unsubstituted ethenyl group, a substituted or unsubstituted propenyl group, a substituted or unsubstituted butenyl group, a substituted or unsubstituted ethynyl group, a substituted or unsubstituted propynyl group, a substituted or unsubstituted butynyl group, a substituted or unsubstituted benzyl group, a substituted or unsubstituted methoxy group, a substituted or unsubstituted ethoxy group, a substituted or unsubstituted propoxy group, or a combination thereof,
R² is a substituted or unsubstituted cyclopropyl group, a substituted or unsubstituted cyclobutyl group, a substituted or unsubstituted cyclopentyl group, a substituted or unsubstituted cyclohexyl group, a substituted or unsubstituted phenyl group, a substituted or unsubstituted naphthyl group, a substituted or unsubstituted anthracenyl group, a substituted or unsubstituted tolyl group, a substituted or unsubstituted xylene group, a substituted or unsubstituted pyridine group, a substituted or unsubstituted pyrrolidine group, a substituted or unsubstituted piperidine group, a substituted or unsubstituted pyrrolyl group, a substituted or unsubstituted furanyl group, a substituted or unsubstituted tetrahydrofuranyl group, a substituted or unsubstituted pyranyl group, a substituted or unsubstituted tetrahydropyranyl group, a substituted or unsubstituted dioxane group, a substituted or unsubstituted morpholine group, or a combination thereof,
R^{b} is a substituted or unsubstituted methyl group, a substituted or unsubstituted ethyl group, a substituted or unsubstituted propyl group, a substituted or unsubstituted butyl group, a substituted or unsubstituted isopropyl group, a substituted or unsubstituted tert-butyl group, substituted or unsubstituted tert-pentyl group, a substituted or unsubstituted 2,2-dimethylpropyl group, a substituted or unsubstituted cyclopropyl group, a substituted or unsubstituted cyclobutyl group, a substituted or unsubstituted cyclopentyl group, a substituted or unsubstituted cyclohexyl group, a substituted or unsubstituted ethenyl group, a substituted or unsubstituted propenyl group, a substituted or unsubstituted butenyl group, a substituted or unsubstituted ethynyl group, a substituted or unsubstituted propynyl group, a substituted or unsubstituted butynyl group, a substituted or unsubstituted phenyl group, a substituted or unsubstituted tolyl group, a substituted or unsubstituted xylene group, a substituted or unsubstituted benzyl group, or a combination thereof, and
R^{c}, R^{d}, R^{e}, R^{f}, R^{g}, R^{h}, Rⁱ, R^{j}, R^{k}, and R^{l} are each independently hydrogen, a substituted or unsubstituted methyl group, a substituted or unsubstituted ethyl group, a substituted or unsubstituted propyl group, a substituted or unsubstituted butyl group, a substituted or unsubstituted isopropyl group, a substituted or unsubstituted tert-butyl group, a substituted or unsubstituted tert-pentyl group, a substituted or unsubstituted 2,2-dimethylpropyl group, a substituted or unsubstituted cyclopropyl group, a substituted or unsubstituted cyclobutyl group, a substituted or unsubstituted cyclopentyl group, a substituted or unsubstituted cyclohexyl group, a substituted or unsubstituted ethenyl group, a substituted or unsubstituted propenyl group, a substituted or unsubstituted butenyl group, a substituted or unsubstituted ethynyl group, a substituted or unsubstituted propynyl group, a substituted or unsubstituted butynyl group, a substituted or unsubstituted phenyl group, a substituted or unsubstituted tolyl group, a substituted or unsubstituted xylene group, a substituted or unsubstituted benzyl group, or a combination thereof.

6. The semiconductor photoresist composition as claimed in claim 1, wherein
the second organometallic compound is any one selected from among compounds listed in Group 2:

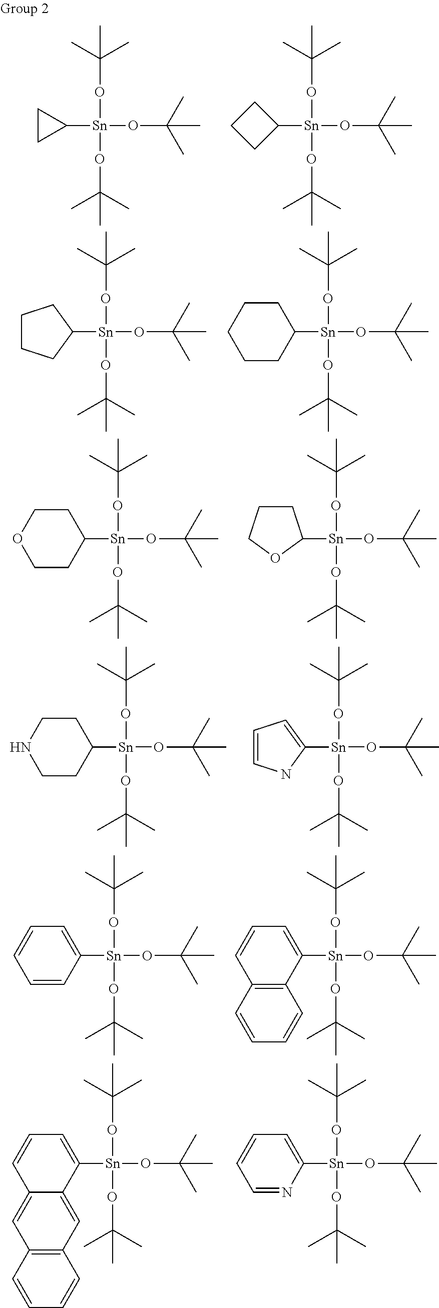

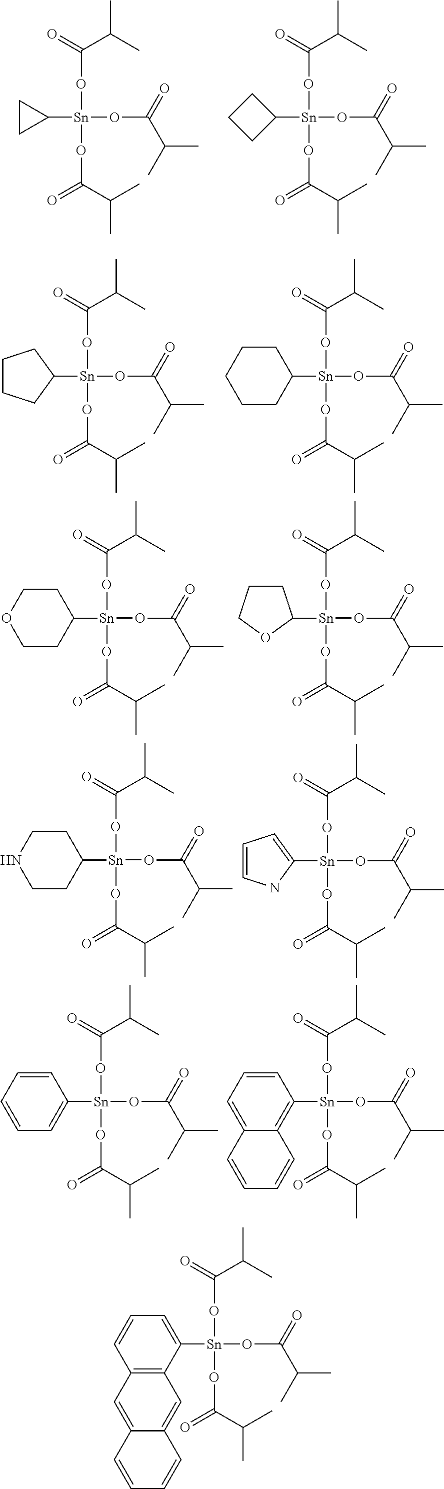

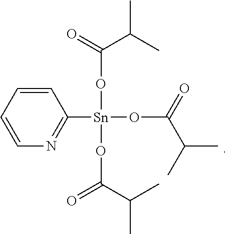 [SMILES: CC(C)C(=O)[O][Sn]([O]C(=O)C(C)C)([O]C(=O)C(C)C)[c]1ccccn1]

7. The semiconductor photoresist composition as claimed in claim 1, wherein
the first organometallic compound is any one selected from among compounds listed in Group 1:

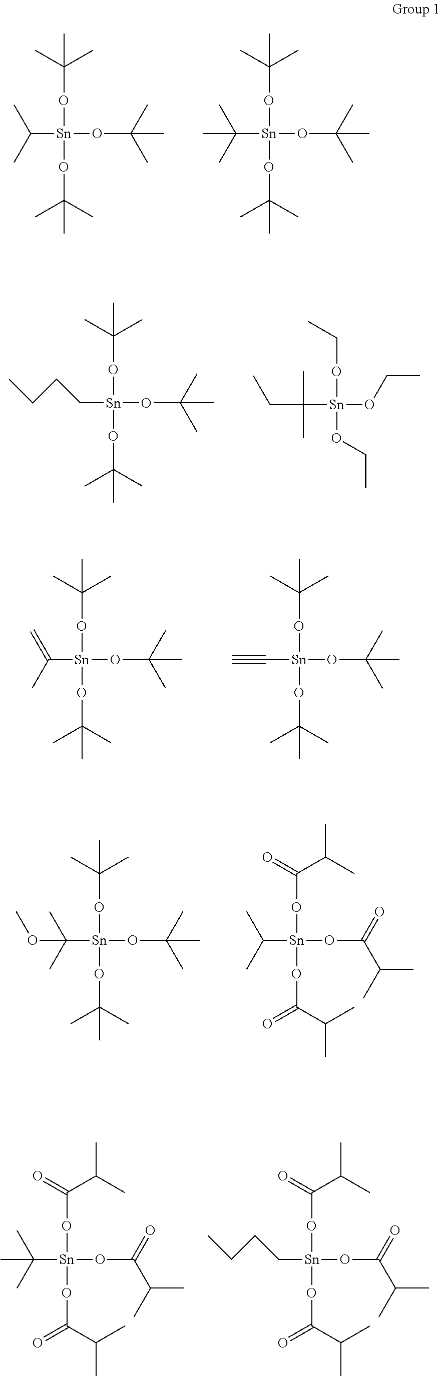

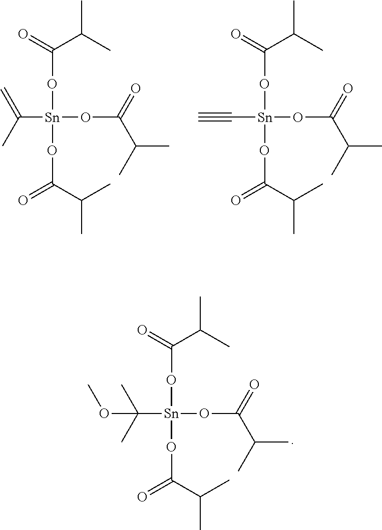

8. The semiconductor photoresist composition as claimed in claim 1, wherein
the first organometallic compound is in an amount of about 1 wt % to about 30 wt %, and the second organometallic compound is in an amount of about 1 wt % to about 30 wt %, based on 100 wt % of a total weight of the semiconductor photoresist composition.

9. The semiconductor photoresist composition as claimed in claim 1, wherein
the semiconductor photoresist composition further comprises an additive selected from among a surfactant, a crosslinking agent, a leveling agent, an organic acid, a quencher, or a combination thereof.

10. A method of forming patterns, comprising:
forming an etching-objective layer on a substrate;
coating the semiconductor photoresist composition as claimed in claim 1 on the etching-objective layer to form a photoresist layer;
patterning the photoresist layer to form a photoresist pattern; and
etching the etching-objective layer utilizing the photoresist pattern as an etching mask.

11. The method as claimed in claim 10, wherein
the forming of the photoresist pattern is utilizing light with a wavelength of about 5 nm to about 150 nm.

12. The method as claimed in claim 10, wherein
the method further comprises providing a resist underlayer between the substrate and the photoresist layer.

13. The method as claimed in claim 10, wherein
the photoresist pattern has a width of about 5 nm to about 100 nm.
